(19) United States
(12) Patent Application Publication
(10) Pub. No.: US 2022/0199543 A1
(43) Pub. Date: Jun. 23, 2022

(54) ELECTRONIC SUBASSEMBLY AND ELECTRONIC ASSEMBLAGE

(71) Applicant: Robert Bosch GmbH, Stuttgart (DE)

(72) Inventors: Irfan Aydogmus, Nuertingen (DE); Gerhard Braun, Rottenburg (DE); Markus Moeller, Pfullingen (DE)

(21) Appl. No.: 17/603,887

(22) PCT Filed: May 7, 2020
(86) PCT No.: PCT/EP2020/062703

§ 371 Date: Oct. 14, 2021

(30) Foreign Application Priority Data
May 20, 2019 (DE) 10 2019 207 341.7

(51) Int. Cl. H01L 23/532; H01L 23/498

(52) U.S. Cl. CPC H01L 23/53219; H01L 23/49811; H01L 23/53223

(57) ABSTRACT

An electronic subassembly encompassing at least one carrier substrate, an electronic circuit being embodied on at least one carrier substrate surface. The electronic subassembly encompasses at least one mechanical connecting boss that is connected, in a substrate connection region, to at least one of the carrier substrate surfaces. The connecting boss, conversely, has, on a side facing away from the substrate connection region, a terminating boundary layer which is made of a metal oxide and which is embodied to furnish an adhesive bonding surface for an adhesive layer in order to constitute an adhesively bonded composite assemblage with a join participant.

### FIELD

The present invention relates to an electronic subassembly and to an electronic assemblage encompassing at least the one electronic subassembly.

### BACKGROUND INFORMATION

Electronic circuits are configured on carrier substrates, for example on a standard circuit board made of FR4 material. The electronic circuit encompasses a conductor structure by way of which electronic components are electrically contacted to one another. For assembly, the carrier substrates are then bolted or riveted, for example, into a housing in order to achieve a fixed mechanical connection thereto. Alternatively, there are also reasons to consider implementing such connections by way of an intermaterial join, and to adhesively bond the circuit board. Such bonding obligatorily requires a controlled good surface quality, however. This is critical in particular if the adhesive bond is also intended to transfer mechanical loads (structural bond). This requirement for high surface quality encounters some difficulties, however, that arise from conventional structural and connection technology. The various typical metallic conductive surfaces of circuit boards, for example (e.g., gold, copper, tin, etc.), and their coatings (OSP, solder resist, etc.) are fairly problematic for structural adhesive connections. What occurs in particular, as a rule, is poor adhesion capability for these surfaces or coatings, which can result over time during operation in cracking and/or delamination, in particular due to temperature fluctuations and mechanical action. In addition, the manufacture of circuit boards often requires the use of media that later have a disadvantageous effect on the adhesive bonds, to the point of destroying adhesive properties. Process monitoring that ensures subsequent removal of these process media from the circuit boards is extremely laborious and is often not implemented by manufacturers. On the whole, the operating reliability of a structural adhesive bond is therefore very difficult to safeguard or guarantee.

### SUMMARY

The object on which the present invention is based is that of ensuring a simple and reliable load-transferring join between an electrically populated carrier substrate and a further join participant, thereby constituting an electronic assemblage.

This object is achieved by an electronic subassembly, and an electronic assemblage encompassing at least the one electronic subassembly, in accordance with example embodiments of the present invention.

The present invention proceeds from an electronic subassembly encompassing at least one carrier substrate, an electronic circuit being embodied on at least one carrier substrate surface. In accordance with an example embodiment of the present invention, the electronic subassembly encompasses at least one mechanical connecting boss that is connected, in a substrate connection region, to at least one of the carrier substrate surfaces. Preferably, the one side of the connecting boss which faces toward the substrate connection region is connected to a metallization region disposed on the carrier substrate surface. The connected metallization region can be embodied structurally identically or structurally similarly to an electrical conductor structure embodied on the carrier substrate surface; in particular, an electrical connection to the conductor structure does not, or need not obligatorily, exist. The connection region can also be introduced, by way of example, as a metallic inlay in the carrier substrate. The connecting boss, on the other hand, has, on a side facing away from the substrate connection region, a terminating boundary layer which is made of a metal oxide and which is embodied to furnish an adhesive bonding surface for an adhesive layer in order to constitute an adhesively bonded composite assemblage with a join participant. Advantageously, oxide layers offer surface boundary layers to which adhesives can attach in outstandingly well-adhering fashion. In this regard, the above-described connecting boss now creates an ideal connecting interface of the electronic subassembly in order to constitute a structural adhesive bond with any bond participants. The metal oxide is embodied, for example, as an oxidized outer layer of a base material made of the elemental metal. Alternatively, an at least locally disposed metal-oxide outer coating can be applied onto an adhering base material, for example a metal or a metal alloy, using coating conventional methods, for example a plasma coating method.

In an advantageous embodiment of the electronic subassembly in accordance with the present invention, the connecting boss is constituted substantially, or at least in portions on a side facing toward the furnished adhesive bonding surface, from aluminum or from an aluminum alloy, in particular an aluminum oxide. Aluminum has the advantage that its surfaces can be cleaned easily and effectively, so that a defined joining surface can be configured in preparatory fashion. In addition, with technical assistance and/or independently, adherent and durably stable oxides form on those surfaces and ensure adhesive attachment to adhesive substances. Regions outside the furnished adhesive bonding surface, in particular a core of the connecting boss, can thus be made from aluminum, while the furnished adhesive bonding surface is made of aluminum oxide. It is also possible, for economic reasons, to provide any aluminum-containing volumetric portion of the connecting boss entirely as aluminum oxide.

In a preferred embodiment of the electronic subassembly of the present invention, the connecting boss has, at least on the side facing toward the substrate connection region, an applied adhering metallization that is made in particular of Cu, Ag, Ni, Au, or an alloy thereof. The advantageous result is that there exists a joining interface to the carrier substrate which can be fixedly connected to the substrate carrier surface using conventional joining methods, in particular to a metallization region disposed on the substrate carrier surface. The overall result thereby achievable is that the connecting boss has a high load-carrying capacity thanks to the load-carrying joining interface with respect to the carrier substrate on the one hand, and thanks to the load-carrying adhesive interface to a join participant of the electronic subassembly on the other hand. The metallization is preferably applied by electroplating, for example being made of silver or a silver alloy. An advantageous alternative metallization is provided by a metal sheet roll-bonded onto a connecting boss core. For example, a copper sheet is connected by roll-bonding to a connecting boss core made of aluminum.

A particularly advantageous embodiment of the electronic subassembly of the present invention is one in which the connecting boss is connected to the carrier substrate by way of a solder layer or a sintered layer in the substrate connection region, the connecting boss having, at least in the substrate connection region, a solderable and/or sinterable boundary layer that terminates toward the solder layer or sintered layer. This solderable and/or sinterable boundary layer is, for example, the aforementioned metallization. Alternatively, the connecting boss in essence, or at least that side of the connecting boss which faces toward the substrate connection region, can be constituted from a solderable and/or sinterable core material, in particular a metal or a metal alloy, for example a copper alloy. Advantageously, the connecting boss can thereby be soldered or sintered to the carrier substrate in a preferably conjoint process of populating the carrier substrate with electrical and/or electronic components.

An alternative advantageous embodiment of the electronic subassembly of the present invention provides that the connecting boss is connected to the carrier substrate in the substrate connection region by way of a nonpositive and/or positive connection, in particular a press-in contact. A press-in pin or press-in orifice can, for instance, be shaped out of or into the connecting boss, for example on a roll-bonded copper sheet. The complementary press-in participant is then embodied on the carrier-substrate side, for example as a metallized press-in orifice or as a press-in pin already contacted to the carrier substrate. Press-in technology is already an established and well-controlled production standard for series manufacturing.

The present invention also leads to an electronic assemblage encompassing at least one first electronic subassembly according to at least one of the embodiments described above, and to a join participant, the join participant being connected, in a connection region, at least to the one connecting boss by way of an adhesive layer immediately adjacent to the respectively furnished adhesive bonding surface. Advantageously, a load-transferring join that lasts over the service life can thereby be produced. Specifically in the automotive sector, for example, very stringent requirements are applied to the operating reliability of electronic subassemblies and assemblages, since ordinary joins, in particular conventional structural adhesive bonds in electronic subassemblies, can be damaged within the operating lifetime as a result of frequent temperature alternations and/or mechanical action, for example vibration. It is particularly preferred to use adhesives such as epoxy adhesives or silicone adhesives.

In a preferred embodiment of the electronic subassembly of the present invention, the join participant is a housing part or at least a second electronic subassembly in accordance with at least one of the embodiments described above. In an assemblage of two aforesaid electronic subassemblies, the latter are disposed one above another, the connection region between two mutually facing adhesive bonding surfaces then being constituted respectively by a connecting boss of the first and of the second electronic subassembly. Particularly preferably, the two adhesively bonded connecting bosses are respectively connected to substrate surfaces of the carrier substrates of the first and of the second electronic subassembly which are disposed parallel to one another, so that a very stable and compact stacked assemblage exists. Also configurable in principle is an electronic assemblage in which the carrier substrates of the first and of the second electronic subassembly are adhesively joined by way of the respective connecting bosses at an angle to one another, in particular a perpendicular angle to one another.

When a housing part constitutes the join participant that is provided, it is preferably made of aluminum or an aluminum alloy. The housing part exhibits, however, at least in the connection region, objective features that correspond to those of the connecting boss for an optimized structural bond. A connecting boss that is identical in principle can, for example, be disposed or embodied on the housing side.

In general, in order to simplify a joining process, in an embodiment of the electronic assemblage provision is advantageously made that one of the mutually facing adhesion surfaces of the connecting bosses encloses the other adhesion surface preferably in planar fashion, so that the electronic assemblage can be reliably configured despite joining tolerances.

In a particularly favorable embodiment of the electronic assemblage of the present invention encompassing two previously described embodiments of an electronic subassembly, the electronic circuits of the first and of the second electronic subassembly are electrically connected to one another by way of at least one electrically conductive connecting element. In addition, preferably the first electronic subassembly has a power circuit, and the second electronic subassembly has a circuit for applying control to the power circuit.

Advantageously, substrate types that are optimized or obligatorily necessary for the respective electronic circuit can thereby be utilized. For example, the power circuit is then embodied in particular on a DBC, AMB, IMS, LTCC, or HTCC carrier substrate, while the control application circuit is disposed on a circuit board, in particular on a standard FR4 circuit board. The electronic assemblage can therefore advantageously encompass a composite of different substrate types. In addition, the adhesively bonded connecting bosses function as heat paths by way of which the heat occurring in the control application circuit can be discharged into the ceramic carrier substrate of the power circuit. It is then possible, by way of the above-described adhesively bonded electronic assemblage, to dispose a control application circuit, for example on an FR-4 circuit board, very close to the ceramic carrier substrate which, for example, contains power semiconductors for a bridge circuit. This proximity of the control application circuit or driver circuit makes possible very low-inductance and symmetrical electrical control application to the power semiconductors. Considerable advantages in terms of circuit performance, for instance for an electric drive system, result therefrom. In addition, it is now possible in this manner to structurally bond within an electronic assemblage, in a load-bearing manner and over the service life, circuit boards that are otherwise very difficult to adhesively bond.

In an advantageous refinement of the electronic assemblage of the present invention, the electrically conductive connecting element is a bonding wire or bonding ribbon. Alternatively, it is also possible to use a flexible (ribbon) cable that, soldered at both ends, connects the two electronic circuits to one another or has a plug connection at least at one end or at both ends for electrical connection.

In a further advantageous refinement of the electronic assemblage of the present invention, the carrier substrates of the first and of the second electronic subassembly are disposed in parallel fashion one above another. In addition, a first bond connection point of the electrically conductive connecting element is embodied on that substrate surface of the carrier substrate of the second electronic subassembly which faces away from the substrate connection region. The physical disposition is, in particular, such that in a projection of a plan view onto the aforesaid substrate surface, the first bond connection point is disposed laterally inside the respective substrate connection region of the carrier substrate of the first and/or of the second electronic subassembly. The connecting bosses thereby act, during a bonding process, so as to function as mechanical supporting elements by which the forces that act during bonding can be absorbed without damage.

For simplified embodiment and utilization of a bond process technology, a second bond connection point of the electrically conductive connecting element is embodied on that substrate surface of the carrier substrate of the first electronic subassembly which faces toward the substrate connection region, such that in a plan view of the first bond connection point, the second bond connection point is disposed in freely accessible fashion with a lateral offset from an outer edge of the carrier substrate of the second electronic subassembly. This is accomplished in an embodiment such that the second bond connection point is, in particular, freely accessible for a bonding tool. Bonding can thus be accomplished after the electronic assemblage exists as an adhesively bonded composite of two electronic subassemblies. In addition, it also thereby becomes possible to perform bonding over different planes of the disposed carrier substrates of the two electronic subassemblies.

The two bond connection points can be connected to at least one part of the electrical conduction structure of the respective electronic subassembly. For example, the first bond connection point encompasses a contact pad of the carrier substrate of the second electronic subassembly, and the second bond connection point encompasses a contact pad of the carrier substrate of the first electronic subassembly. Alternatively, the second bond connection point is connected to a contact terminal of a power semiconductor disposed on the carrier substrate of the first electronic subassembly.

In a particular refinement of the electronic assemblage of the present invention, the carrier substrate of the second electronic subassembly has at the edge at least one cutout open on one side or on two sides, such that in a projection of a plan view of the bonded substrate surface of the carrier substrate of the second electronic subassembly, the second bond connection point is disposed laterally inside the cutout. A very compact circuit disposition of both the first electronic subassembly and the second electronic subassembly can thereby be implemented. Preferably, a region of the carrier substrate of the second electronic subassembly which is adjacent to the cutout then has a first bond connection point. Also preferably, the bonded composite of each two connecting bosses is disposed below the first bond connection point, constituting additional mechanical support elements for a bonding process.

In general, a plurality of connecting bosses respectively of the first and of the second electronic substrate, adhesively bonded in pairs, can be embodied within the electronic assemblage. Preferably, all the connecting bosses of one or both electronic subassemblies, or at least the majority of connecting bosses of one or both electronic subassemblies, are embodied identically. Divergently therefrom, in order to meet local needs at least two connecting bosses can differ within an electronic subassembly and/or between the two electronic subassemblies.

In addition, several join participants, encompassing at least one or several of a described embodiment of the electronic subassembly, can be disposed next to and/or above one another as a composite assemblage, by way of structural adhesive bonds between complementary connecting bosses of each two join participants.

### BRIEF DESCRIPTION OF THE DRAWINGS

Further advantages, features, and details of the present invention are evident from the description below of preferred exemplifying embodiments and with reference to the figures.

FIG. 1 is a lateral section view of an electronic assemblage encompassing at least one electronic subassembly and a join participant adhesively bonded to it, in accordance with an example embodiment of the present invention.

FIG. 2 is a plan view of the electronic assemblage of FIG. 1.

### DETAILED DESCRIPTION OF EXAMPLE EMBODIMENTS

In the Figures, functionally identical components are labeled in each case with identical reference characters.

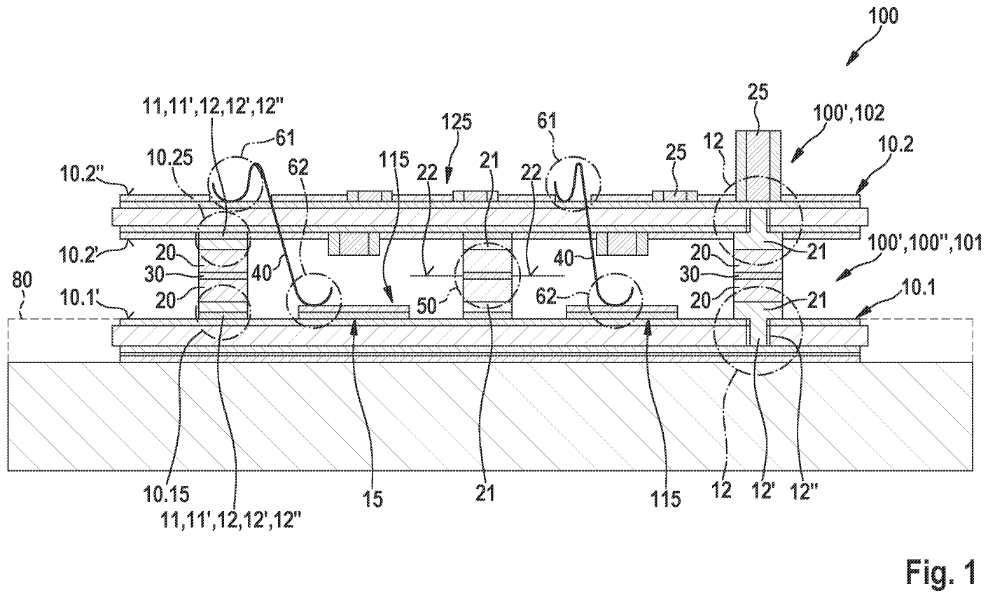

FIG. 1 is a lateral section view of an exemplifying embodiment of an electronic assemblage 100. Electronic assemblage 100 encompasses at least one electronic subassembly 100′ having a carrier substrate 10.1, 10.2 populated on at least one side, and a join participant 100″ connected by way of an adhesively bonded connection to electronic subassembly 100′. What is shown in particular is an exemplifying embodiment in which a first electronic subassembly 101 and a second electronic subassembly 102 are disposed one above another, so that carrier substrate surfaces 10.1′, 10.2′ of the respective electronic subassemblies 101, 102 face one another with a parallel spacing from one another. The mutually facing carrier substrate surfaces 10.1′, 10.2′ have at least one connecting boss 20 which projects from carrier substrate surface 10.1′, 10.2′ and is connected, for example by way of a solder layer 11 or a sintered layer 11′, to the respective carrier substrate 10.1, 10.2 in a substrate connection region 10.15, 10.25. Alternatively, a fixed connection exists by way of a press-in contact 12, for example encompassing a press-in pin 12.1 and a press-in orifice 12″ which are respectively shaped on and out of connecting boss 20 and carrier substrate 10.1, 10.2 in complementary fashion to one another (depicted by way of example in FIG. 1 in the electronic assemblage at the two outer right-hand connecting bosses 20). The respective end regions of two connecting bosses 20 of the first and the second electronic subassembly 101, 102 are located opposite one another in a connection region 50. These end regions facing one another each have a terminating boundary layer made of a metal oxide, which is embodied to furnish an adhesive bonding surface 22 for an adhesive layer 30 in order to constitute an adhesively bonded composite assemblage with a join participant. The two adhesive bonding surfaces 22 of the two connecting bosses 20 are connected to one another by way of an adhesive layer 30 that is adjacent to them and adheres fixedly to them. In the present exemplifying embodiment, three adhesively connected complementary connecting bosses 20 are shown in the section view. Alternatively, more or fewer pairs can be provided in application-specific fashion. The connecting bosses are preferably constituted from an aluminum, an aluminum alloy, or an aluminum oxide. A boundary layer having an oxide necessary for the adhesive connection is thus ensured in connection region 50. In substrate connection region 10.15, 10.25, the respective connecting boss 20 has an additional metallization 21 made, for example, of Ag, Cu, Ni, Au, or an alloy thereof. In particular, metallization 21 has at least one sinterable and/or solderable boundary layer. Metallization 21 is applied, for example, by electroplating. Alternatively, a copper sheet constituting metallization 21 can be connected by roll-bonding to the aluminum-containing core of connecting boss 20 in substrate connection region 10.15, 10.25. The copper sheet then alternatively has a respectively shaped-out or shaped-on press-in pin 12′ or press-in orifice 12″. In principle, connecting boss 20 can also be made of any, in particular metallic, core material that has a sinterable and/or solderable coating in substrate connection region 10.15, 10.25, and an adhesively bondable coating, made of a metal oxide, in connection region 50.

First and second electronic subassembly 101, 102 each have an electronic circuit 115, 125. The latter are electrically connected to one another by way of at least one electrically conductive connecting element 40, in particular a bonding wire or a bonding ribbon. First electronic subassembly 101 preferably has a power circuit 115 having at least one power semiconductor 15 that is disposed, for example soldered or sintered, on a DBC, AMB, IMS, LTCC, or HTCC substrate 10.1. Also preferably, second electronic subassembly 102 has a circuit 125 for control application to power circuit 115, having at least one soldered or sintered electrical and/or electronic component 25. Electrical and/or electronic component 25 is disposed in particular on a circuit board constituting carrier substrate 10.2, for example a standard F4 circuit board. A first bond connection point 61 of electrically conductive connecting element 40 is embodied on that substrate surface 10.2″ of carrier substrate 10.2 of second electronic subassembly 102 which faces away from substrate connection region 10.25. First bond connection point 61 is disposed directly above the adhesively connected connecting bosses 20, so that mechanical forces acting in the context of a bonding process can be absorbed in supporting fashion. The bonded connection is made, for example, on a metallic contact pad that is provided for the purpose and is embodied structurally identically or structurally similarly to an electrical conductor structure disposed on carrier substrate surface 10.2′.

A second bond connection point 62 of electrically conductive connecting element 40 is embodied, conversely, on that substrate surface 10.1′ of carrier substrate 10.1 of first electronic subassembly 101 which faces toward substrate connection region 10.15. In this exemplifying embodiment, the bonded connection is made to an upper contact terminal of a power semiconductor 15 disposed on carrier substrate 10.1 of first electronic subassembly 101. Alternatively, a bonded connection can also be made to a contact path, similarly or identically to the case with first bond connection point 61. As depicted in FIG. 1, the two circuits 115, 125 can be connected to one another with more than one connecting element 40.

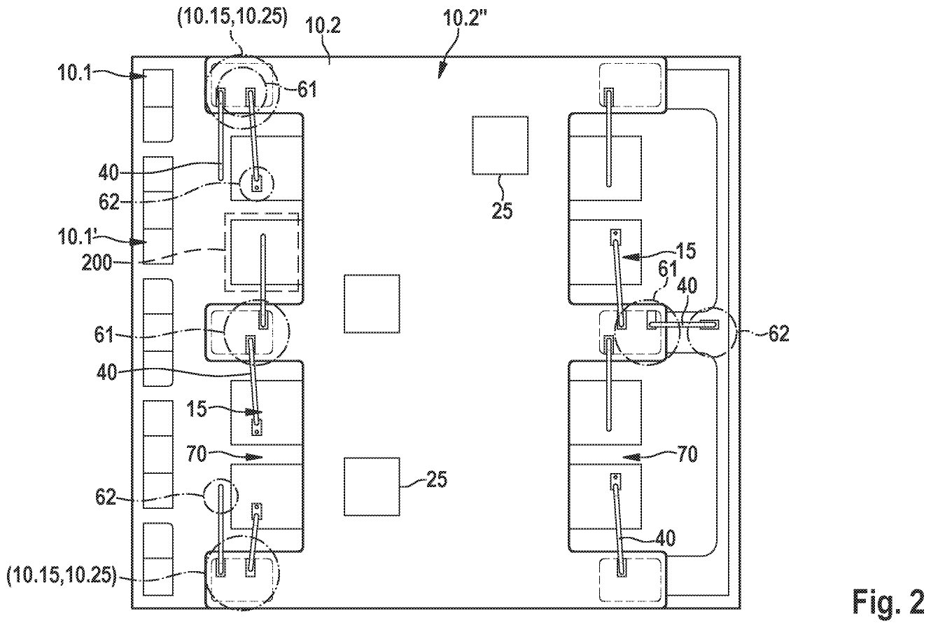

FIG. 2 is a plan view of the electronic assemblage of FIG. 1. It is evident that in a projection of the plan view onto carrier substrate surface 10.2″, first bond connection point 61 is disposed laterally inside the respective substrate connection region 10.15, 10.25 of carrier substrate 10.1, 10.2 of first and/or second electronic subassembly 101, 102. It is additionally evident that in a plan view of first bond connection point 61, second bond connection point 62 is disposed, with a lateral offset from an outer edge of carrier substrate 10.2 of second electronic subassembly 102, in freely accessible fashion, in particular freely accessibly to a bonding tool 200 (depicted with dashed lines). In order to implement a compact electronic subassembly 101, 102, in this exemplifying embodiment carrier substrate 10.2 of second electronic subassembly 102 has at the edge at least one cutout 70 open on one side or on two sides. In a projection of the plan view onto the bonded carrier substrate surface 10.2′ of carrier substrate 10.2 of second electronic subassembly 102, it is evident that second bond connection point 62 is disposed laterally inside cutout 70.

A further embodiment of an electronic assemblage 100 is obtained from the fact that one electronic subassembly 100′ is no longer connected, as already described, to another electronic subassembly 100′ but is now connected to another join participant 100″, the other join participant 100″ having an adhesively bondable joining surface. The latter can in turn be furnished by a connecting boss 20 that is embodied in one piece with, or connected to, join participant 100″. FIG. 1 therefore shows a further electronic assemblage 100 in which, for example, electronic subassembly 102 is structurally adhesively bonded not to electronic subassembly 102 but instead to a housing part 80. The housing part is preferably made of aluminum or an aluminum alloy, so that connecting bosses shaped or disposed there have a boundary layer of aluminum oxide. Alternatively, in the context of a different housing material, corresponding connecting bosses 20 can be provided which form an adhesively bonded composite assemblage pairwise with a connecting boss 20 of second electronic subassembly 102.

Generally, adhesive can be applied, for example by way of a dispensing operation, onto adhesive bonding surface 22 on the connecting boss of one of join participants 101, 102, 70. The other join participant 101, 102, 70 can then be brought, for example by a handling apparatus, into a configuration in which connecting bosses 20 of the respective join participants 101, 102, 70 are located with their adhesive bonding surfaces 22 pairwise opposite one another, and are respectively wetted by the adhesive to form the adjoining adhesive layer 30. A load-transferring adhesive connection is produced as soon as the adhesive has cured.

1-15. (canceled)

16. An electronic subassembly, comprising:
at least one carrier substrate having carrier substrate surfaces;
an electronic circuit embodied on at least one of the carrier substrate surfaces; and
at least one mechanical connecting boss that is connected, in a substrate connection region, to at least one of the carrier substrate surfaces, the connecting boss having, on a side facing away from the substrate connection region, a terminating boundary layer which is made of a metal oxide and which is embodied to furnish an adhesive bonding surface for an adhesive layer to constitute an adhesively bonded composite assemblage with a join participant.

17. The electronic subassembly as recited in claim 16, wherein the connecting boss is constituted substantially, or at least in portions on a side facing toward the furnished adhesive bonding surface from aluminum or from an aluminum alloy.

18. The electronic subassembly as recited in claim 17, wherein the connecting boss is constituted from an aluminum oxide.

19. The electronic subassembly as recited in claim 17, wherein the connecting boss has, at least on the side facing toward the substrate connection region, an applied adhering metallization that is made of Cu or Ag or Ni or Au, or an alloy of Cu or an alloy of Ag or an alloy of Ni or an alloy of Au.

20. The electronic subassembly as recited in claim 19, wherein the metallization is applied by electroplating or is applied as a roll-bonded metal sheet.

21. The electronic subassembly as recited in claim 19, wherein the metallization is applied by electroplating using silver, or is applied as a roll-bonded copper sheet.

22. The electronic subassembly as recited in claim 16, wherein the connecting boss is connected to the carrier substrate using a solder layer or a sintered layer in the substrate connection region, the connecting boss having, at least in the substrate connection region, a solderable and/or sinterable boundary layer that terminates toward the solder layer or the sintered layer.

23. The electronic subassembly as recited in claim 16, wherein the connecting boss is connected to the carrier substrate in the substrate connection region using a nonpositive and/or positive connection.

24. The electronic subassembly as recited in claim 16, wherein the connecting boss is connected to the carrier substrate in the substrate connection region using a press-in contact.

25. An electronic assemblage, comprising:
at least one first electronic subassembly including:
at least one carrier substrate having carrier substrate surfaces,
an electronic circuit embodied on at least one of the carrier substrate surfaces, and
at least one mechanical connecting boss that is connected, in a substrate connection region, to at least one of the carrier substrate surfaces, the connecting boss having, on a side facing away from the substrate connection region, a terminating boundary layer which is made of a metal oxide and which is embodied to furnish an adhesive bonding surface; and
the join participant connected, in a connection region, at least to the connecting boss by way of an adhesive layer immediately adjacent to the furnished adhesive bonding surface.

26. The electronic assemblage as recited in claim 25, wherein the join participant is a housing part.

27. The electronic assemblage as recited in claim 25, wherein the join participant is at least a second electronic subassembly, the second subassembly including at least one carrier substrate having carrier substrate surfaces, an electronic circuit embodied on at least one of the carrier substrate surfaces, and at least one mechanical connecting boss that is connected, in a substrate connection region, to at least one of the carrier substrate surfaces, the connecting boss having, on a side facing away from the substrate connection region, a terminating boundary layer which is made of a metal oxide and which is embodied to furnish an adhesive bonding surface, wherein the first and second electronic subassemblies are disposed one above another and a connection region between two mutually facing adhesive bonding surfaces of the first and second electronic subassemblies are constituted respectively by the connecting boss of the first and of the second electronic subassembly.

28. The electronic assemblage as recited in claim 27, wherein the two adhesively bonded connecting bosses are respectively connected to substrate surfaces of the carrier substrates of the first and of the second electronic subassembly which are disposed parallel to one another.

29. The electronic assemblage as recited in claim 27, wherein the electronic circuits of the first and of the second electronic subassembly are electrically connected to one another by way of at least one electrically conductive connecting element.

30. The electronic assemblage as recited in claim 29, wherein the first electronic subassembly has a power circuit and the second electronic subassembly has a circuit for applying control to the power circuit.

31. The electronic assemblage as recited in claim 29, wherein the electrically conductive connecting element is a bonding wire or bonding ribbon.

32. The electronic assemblage as recited in claim 31, wherein the carrier substrates of the first and of the second electronic subassembly are disposed in parallel fashion one above another, and a first bond connection point of the electrically conductive connecting element is embodied on a first substrate surface of the carrier substrate of the second electronic subassembly which faces away from the substrate connection region, such that in a projection of a plan view onto the first substrate surface, the first bond connection point is disposed laterally inside the substrate connection region of the carrier substrate of the first and/or of the second electronic subassembly.

33. The electronic assemblage as recited in claim 32, wherein a second bond connection point of the electrically conductive connecting element is embodied on a second substrate surface of the carrier substrate of the first electronic subassembly which faces toward the substrate connection region, such that in a plan view of the first bond connection point, the second bond connection point is disposed in freely accessible fashion for a bonding tool, with a lateral offset from an outer edge of the carrier substrate of the second electronic subassembly.

34. The electronic assemblage as recited in claim 33, wherein the first bond connection point encompasses a contact pad of the carrier substrate of the second electronic subassembly, and the second bond connection point encompasses a contact pad of the carrier substrate of the first electronic subassembly or an upper contact terminal of a power semiconductor disposed on the carrier substrate of the first electronic subassembly.

35. The electronic assemblage as recited in claim 33, wherein the carrier substrate of the second electronic subassembly has at an edge at least one cutout open on one side or on two sides, such that in a projection of a plan view of a bonded substrate surface of the carrier substrate of the second electronic subassembly, the second bond connection point is disposed laterally inside the cutout.
